(19) United States
(12) Patent Application Publication
(10) Pub. No.: US 2005/0256662 A1
(43) Pub. Date: Nov. 17, 2005

(54) Test apparatus

(76) Inventor: Michael John Alder, Lancashire (GB)

Correspondence Address: NIXON & VANDERHYE, PC, 901 NORTH GLEBE ROAD, 11TH FLOOR, ARLINGTON, VA, 22203, US

(21) Appl. No.: 10/513,293

(22) PCT Filed: May 2, 2003
(86) PCT No.: PCT/GB03/01954

§ 371 Date: Nov. 3, 2004

(30) Foreign Application Priority Data
May 7, 2002 (GB) 02104503

(51) Int. Cl. G01R 31/00

(52) U.S. Cl. 702/119

(57) ABSTRACT

Test apparatus comprising: a connector (8) for connecting to the test apparatus (1) a system to be tested, a processor (2) for controlling the operation of the test apparatus and a user interface device (6) for presenting an interface to a user for the provision of input and output, a plurality of test routines (401, 402, 403), each defining a test to be performed on a system to be tested, each test routine having associated information relating to an input user interface (411, 412, 413) and an output user interface (421, 422, 423) to be presented to a user in response to the associated test routine being selected, the processor (2) being arranged, on selection of a particular test routine (401), to present to the user a user interface determined by the information (411, 421) associated with the selected test routine, the user interface being a simulation of the conventional test apparatus normally used to carry out the test routines on the system to be tested.

This invention relates to test equipment and in particular to test equipment for testing multiple functions of a single apparatus or multiple component systems of a larger system.

Complex systems, such as aeronautical, nautical, automotive and submarine systems, involve many electronic and mechanical components, many of which require periodic testing. For instance, the component systems of a commercial aircraft are typically tested after a given number of take-off/landings (e.g. 50). A military aircraft on the other hand is more likely to be tested more often and has many more on-board systems to be tested.

Typically the test equipment used is dedicated to the component system to be tested. Thus if the under-carriage raising/lowering mechanism of an aircraft is to be tested, then a dedicated piece of test equipment is provided that has connection leads specific to that mechanism, test algorithms specific to that mechanism, input/output interface specific to that mechanism etc. Clearly this results in a large volume of test equipment for each multi-component system to be tested. Typically for military aircraft this can be in the order of 1,500 individual pieces of test equipment.

In accordance with the invention there is provided test apparatus comprising:
a connector for connecting to the test apparatus a system to be tested, a processor for controlling the operation of the test apparatus and a user interface device for presenting an interface to a user for the provision of input and output,
a plurality of test routines, each defining a test to be performed on a system to be tested, each test routine having associated information relating to an input user interface and an output user interface to be presented to a user in response to the associated test routine being selected,
the processor being arranged, on selection of a particular test routine, to present to the user a user interface determined by the information associated with the test routine.

Thus the test apparatus is capable of performing a plurality of test routines and, in each case, a unique user interface (UI) is provided to the user in dependence on the test routine being performed. A single piece of test equipment may therefore be used to carry out the testing of a plurality of systems to be tested which obviates the need for the numerous pieces of test equipment that were required formerly. Preferably the input and output user interface presented to a user resembles the UI of the conventional dedicated test equipment. Thus an operator familiar with the conventional test equipment will already be familiar with the UI provided by apparatus according to the invention.

A significant feature of the invention is that the user interface, which is presented in response to the particular system under test (each such system may have a plurality of associated test routines), is a simulation of the user interface of conventional test apparatus normally used to carry out the test routines on that system. This simulation extends to the appearance, layout and operation of the switches, knobs, sliders, gauges, etc of the conventional apparatus. For example, a user may move a pointer on the screen onto the representation of a knob of the input user interface and, by “clicking” on the mouse, the user can turn the knob the requisite amount. In response, the output user interface (e.g. the screen) shows any change on the gauges, meters, etc. exactly as they would be displayed on the conventional apparatus.

Preferably the processor is arranged to identify the system to be tested connected via the connector and, in response to the identification of the connected system to be tested, to select the test routine to be performed based on the identification of the system to be tested. Such identification may be based upon an identification or address code of the system to be tested.

The present invention stores the relevant information according to the type of system (e.g. aircraft) to be tested, and the user inputs the type into the device. The device then recognises the type of sub-system under test (preferably by sensing the type of cabling attached for testing the particular sub-system) and reproduces the associated test routine(s) on screen. The user then manipulates the dials, switches etc. via the input user interface as he would do the conventional test device and the test device then translates those inputs into an analog or digital output signal to produce an output user interface the same as that which the conventional test set would produce in response to those inputs.

The apparatus may further comprise a plurality of test routines from a plurality of suppliers and/or may include a modem.

Preferably the apparatus may comprise a first unit incorporating the test routines and the associated user interface information and a second unit incorporating the user interface device and the connector. Thus the second unit may be portable so meaning that a user is free to move about with the second unit, testing various systems in turn. The test routines may require a high current and/or voltage to be applied to the system under test and in this case it is preferable that the suitable power supply is provided as part of the first unit.

The first and second units may be arranged to communicate via a wireless communication link, for example a radio frequency link, with the first unit being arranged to perform as a wireless hub.

In a second aspect of the invention there is provided a method of testing a system, the method comprising:
connecting to test apparatus a system to be tested,
selecting from a plurality of test routines a test routine to be performed on the system to be tested, said plurality of test routines comprising at least one test routine for each of a plurality of systems to be tested, each test routine having associated information relating to an input user interface and an output user interface to be presented to a user in response to the associated test routine being selected,
on selection of a test routine, presenting to the user a user interface determined by the information associated with the selected test routine.

A test routine may comprise a plurality of sub-routines which relate to the system to be tested and which require the same user input/output interface. For example, if an engine is being tested, sub-routines involving ignition, acceleration, shut-down may be run, with results being presented on the same output interface.

Preferably the method further comprises identifying the system to be tested and, in response to the identification of the connected system to be tested, selecting the test routine to be performed based on the identification of the system to be tested. The system to be tested may be identified by means of an identification or address code of the system to be tested.

A plurality of test routines from a plurality of suppliers may be provided.

In a further aspect of the invention there is provided a computer program product comprising a computer readable medium, having thereon
computer readable program code, when said program is loaded, to make a computer execute procedure to display an interface to a user for the provision of input and output,
computer readable program code comprising a plurality of test routines, each defining a test to be performed on a system to be tested, each test routine having associated information relating to an input user interface and an output user interface to be presented to a user in response to the associated test routine being selected,
computer readable program code, when said program is loaded, to make a computer execute procedure to present to the user, on selection of a particular test routine, a user interface determined by the information associated with the test routine.

The invention will now be described further, by way of example only, with reference to the accompanying drawings, in which:

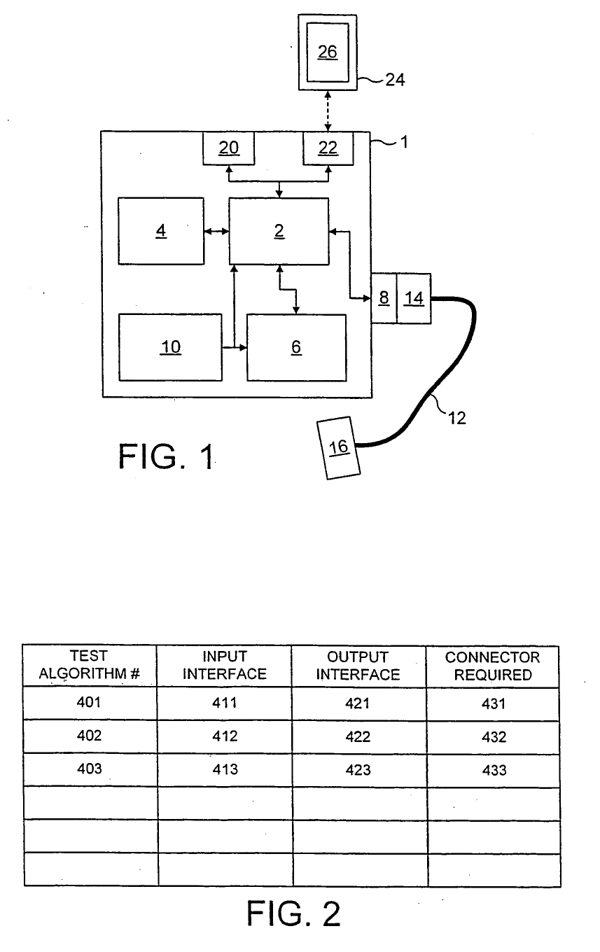

FIG. 1 is a schematic diagram of an embodiment of the test device according to the invention; and

FIG. 2 is a schematic diagram of the database used with the test device of FIG. 1.

As shown in FIG. 1, a test device 1 according to a first embodiment of the invention comprises a central processor 2, memory 4 for storing a database of information, a user interface (UI) device 6, a connector 8, a power supply 10 and a modem 20.

The central processor 2 controls the operation of the test device 1 and may be a suitably programmed microprocessor. Typically the test device 1 is implemented on a ruggedised lap-top computer with a P2-400 MHz (or higher) processor, memory capacity of around 384 MB RAM (or higher), a 25 GB UDMA100 Hard Drive (or larger), Twin Graphics card adapters, Sound Card, CD Read-Write Device, PCI-6052E Data Acquisition (DAQ) Card, PCI-GPIB (General Purpose Instrument Bus) IEEE Card, V90 Modem, 10/100 MB/Sec Ethernet Card, AIM-1553B Duel Stream Card, AIM-PCI429-16 Channel Card,
801.1b Radio Hub, Keyboard & Mouse, TFT Displays. The test equipment is loaded with Windows 98SE, Lab View 6,I, NI-DAQ 6,9 and PC Anywhere V9, 2. The GPIB controls the automatic calibration of the test equipment.

As illustrated in FIG. 2, the database 4 stores a plurality of software routines 401, 402, 403, each of which defines a test algorithm to be carried out by the test device. The database typically contains hundreds of these test routines. Associated with each test routine is: information 411, 412, 413 relating to the input interface that is to be presented to a user on UI device 6 when the associated test routine is being run; information 421, 422, 423 relating to the output interface that is to be presented to the user on UI device 6 when the associated test routine is being run; and information relating to the electrical connector that is to be connected to the connector 8 (and/or the expected inputs to the relevant pins of connector 8) when the associated test is being run.

Thus the user interface presented to a user during the running of a test routine is dependent on the test routine being carried out. In effect, numerous screens can be presented to a user as the test equipment 1 re-configures itself for each test.

As mentioned, a test routine (401, 402, 403 etc) may comprise a plurality of sub-routines related to the system to be tested. However all the sub-routines of a test routine are associated with the same input UI information (411, 412, 413 etc) and output UI Information (421, 422, 423 etc). Thus the same UI is presented to a user for all sub-routines of a given test routine.

The user interface device 6 provides the input/output interface for the test device. Since the test device is suitable for carrying out a plurality of test functions for a plurality of component systems to be tested, the output data for each test to be carried out will be different. For this reason, both the input interface and the output interface of the UI are adaptable. The UI device may involve visual, audio and/or vibratory devices. For instance, the UI device may comprise one or more screens and may involve touch-screen technology, a key-pad or the like. A loudspeaker may be provided to provide audio output, such as providing the user with an audible warning and/or prompts to carry out the test routine.

In a preferred implementation, the user interface device 6 comprises a screen on which the user input/output interface is displayed. This user input/output interface may comprise graphic illustrations of lamps, switches, dials, oscilloscopes, chart recorder representations etc. The idea is that the UI device 6 creates a replica of the input/output functions conventionally associated with the test routine being undertaken. Thus a user familiar with the conventional test apparatus will recognise the test being performed on test equipment according to the invention. The UI device is programmed to define the functionality and the control laws applicable to the specific test routine being carried out. This may be achieved using a graphical programming language.

The test equipment 1 is provided with one or more connectors 8. If a single connector is provided, the connector 8 has a plurality of pins, the number of which is at least as great as the maximum number of electrical connections to a component system to be tested by the test device. Alternatively, the test equipment 1 may be provided with a plurality of connectors 8. In practice, the size of the test equipment tends to be constrained by the number of mechanical connectors 8 required/provided.

A plurality of electrical connector leads 12 (also known as a harness) are provided. Each connector lead has, at the end of the connector lead to be proximal to the test device 1, a connector 14 suitable for plugging into connector 8 and at the end of the connector lead to be distal from the test device a connector 16 suitable for connecting to the component system to be tested.

The power supply may be any appropriate power supply e.g. mains. Alternatively the power supply may be provided by batteries which fit within the test equipment 1, so making the test equipment 1 more portable than if it were attached by hardware to the mains supply. Typically, for use in the aircraft industry, a one hundred channel power supply rated at 15 VDC 20 mA for each output is provided to power up aircraft fuel system level sensors.

The telephone line modem 20 enables real time monitoring/control of the test equipment 1 from anywhere world-wide, only requiring the availability of a telephone line, such as a fixed telephone line or a wireless connection e.g. using mobile phone technology. Thus an expert who is located remote from the test equipment 1 can access the results of tests performed on the test equipment 1 and also control the test equipment via the input UI.

The test equipment also has an Ethernet card to provide the ability for real time monitoring/control over the Internet or internal company networks.

The test equipment may operate as a wireless radio hub using the industry standard 801.1b protocol. A wireless connector 22 on the test equipment 1 communicates with a terminal 24 using the 801.1b protocol thus ensuring no wires are needed for control over a range of approximately one hundred meters. The remote device 24 has a user interface device 26 that reproduces at least part of the UI provided on the test equipment 1. This remote device may take the form of a ruggedised data tablet and provides a user with a local remote control device for the test equipment 1. The remote device may be implemented on a Fujitsu Data Tablet PC with a PCMCIA 801.1b adapter fitted. A user can therefore connect the test apparatus to a system to be tested (e.g. the undercarriage system of an aircraft) using a connector 12 and a second user can take a remote device 24 to the vicinity of the cockpit. The user at the cockpit can then simulate an operation on the undercarriage (e.g. activating the “lower under carriage” button in the cockpit) by altering the UI of the remote device (e.g. activating the appropriate button as represented on the UI 26). This activation is sent to the test equipment 1 via the wireless connection and, in response, the processor alters the UI on the test equipment and simulates the lowering of the under carriage. Thus an operator using the remote device 24 has full flexibility and unrestricted movement whilst performing the test both in and around the aircraft. A user next to the test equipment 1 and the user with the remote device can therefore see the same UI. The remote device 24 may act as a slave or a master with respect to the test equipment 1.

A general purpose instrument bus connection is provided for control of other high-value items of laboratory test equipment—oscilloscopes, vector/scalar network testers and calibration equipment to name only a few. This provides backwards compatibility with the test equipment 1 where high value purchases have been previously made; it also serves to expand the measurement capability of the system in specific areas such as where Radio Frequency and higher speeds are required.

Finally data bus cards are installed for communication with both the ARINC-429 and MIL-1553B protocols, which are found predominantly on both civil and military aircraft in an ever increasing quantity.

All of the hardware features discussed above are fully controlled using the same processor 2 that provides the UI previously described thus providing a fully integrated test solution.

The individual test routines and graphical UI are tailor made to meet each specific requirement, each of which requires a detailed knowledge of the workings of the unit under test.

The test equipment 1 includes signal conditioning components that enable connection of the test equipment 1 to real world signal types including high and low voltage, current, frequency, switches and linear variable differential transformers. These signal conditioning systems (SCX) are permanently wired to the connector(s) 8 of the test equipment. The signal wiring is connected to the modules via removable terminal blocks. These terminal blocks may be pre-wired to general purpose connectors 8. The signal conditioning systems comprise a range of modules that amplify, filter, isolate and multiplex a wide variety of signals types such as thermocouples, strain gauges, high-voltage inputs, current inputs, analogue outputs, digital input/output signals. The signal conditioning systems also provide general purpose multiplexer and matrix switching capabilities.

These signal conditioning systems may comprise the following:

| | |
|---|---|
| SCXI-1001 | 12 Slot Chassis |
| SCXI-1102 | 32 Channel Voltage Input Module |
| SCXI-1121 | 4 Channel RTD Input Module |
| SCXI-1124 | 6 Channel Voltage Output Module |
| SCXI-1125 | 8 Channel Voltage Input Module |
| SCXI-1126 | 8 Channel Frequency Input Module |
| SCXI-1160 | 16 Channel Bi-State Relay Module |
| SCXI-1162HV | 32 Channel HV Digital Input Module |
| SCXI-1163R | 32 Channel Solid State Relay Module |
| SCXI-1180 | SCXI Break-in Adapter |
| SCXI-1346 | Multi Chassis Adapter |
| SCXI-1540 | 8 Channel LVDT Input Module |
| SCXI-1581 | 32 Channel Current Output Module |
| SH68-SH68 | 1 m Interface Cable |

These signal conditioning systems are fully wired to the bank of connectors fitted to the rear of the test equipment 1. Which connector is suitable for which component system to be connected will be clear to a person skilled in the art. Where required other components such as power supplies and relays are fitted between the connectors and signal conditioning hardware. The relays are used to protect the signal conditioning hardware and to enable the test equipment to switch a more realistic load per channel.

The signal conditioning hardware provides a true four wire measurement system which effectively nulls any residual resistance within the system (including the test harness) used to couple from the test equipment 1 to the unit under test.

Thus the test equipment provides an integrated system, with test routines from various suppliers supplied within a single unit, under the total control of a single software package.

The use of Intranet/Internet connection and/or a telephone modem device allows for the control/monitor of a test from anywhere world-wide.

The combination of wireless remote control within a limited range to control/monitor a test locally reduces operator workload.

The unique configuration of the signal conditioning hardware provides a versatile integrated test solution.

In a preferred implementation, the processor 2 is arranged to automatically select the test routine and hence the user interface presented to a user. This may be done by identifying the system to be tested that is connected to the test equipment. The automatic loading of software specific to the test being performed on the system to be tested may be achieved through the use of test harness address codes which, when read by the software, interact with the programme to prevent incorrect operation. These test harness codes may be hardwired into the test harness or connector 12. For instance, a connector 12 may have a plurality of wires, some of which are redundant and the connector 12 may be identified by measuring the resistance across the redundant wires. Each test connector may have a fixed, known resistance connected across the redundant wires, which resistance is stored in the memory 4 of the test equipment 1. Other known ways of identifying a connected component may be used.

Additionally or alternatively, the test equipment 1 may be programmed to present to a user a user interface that requests information relating to the system to be tested and/or the complex system of which the system to be tested is part. Thus a user may input the type of aircraft that is to be tested and, in response, the test equipment provides test routines and user interfaces that relate to that aircraft.

The test equipment, through use of software, provides a unique human-machine interface capable of controlling a single device, providing multiple uses from one common set of hardware.

The test equipment 1 may also be programmed to replicate any interlocks that may be implemented on the complex system incorporating all of the systems to be tested. For instance, in an aircraft, an interlock may be provided to prevent the undercarriage being raised when the aircraft is on the ground. Thus, the test equipment 1 is also programmed with the same interlocks as the aircraft such that, when the undercarriage system is being tested, the undercarriage is not actually raised if the aircraft is on the ground.

The use of software to embed the test procedure required for testing the unit under test automates the execution of the test prompting the operator to carry out certain tasks—but negating the need to monitor the test set at all times.

The test apparatus may be provided in the form of a computer program product comprising a computer readable medium such as a CD or a floppy disc. This computer program product may then be loaded into a computer such as a lap top computer. The computer program product has computer readable program code which, when the program is loaded on a computer, causes the computer to execute procedure to display an interface to a user for the provision of input and output, and to execute procedure to perform one or more of a plurality of test routines defined on the computer program product. The product also includes computer readable program code which, when said program is loaded, makes a computer execute procedure to present to the user, on selection of a particular test routine, a user interface determined by the information associated with the test routine.

1. Test apparatus comprising:
a connector for connecting to the test apparatus a system to be tested, a processor for controlling the operation of the test apparatus and a user interface device for presenting an interface to a user for the provision of input and output,
a plurality of test routines, each defining a test to be performed on a system to be tested, each test routine having associated information relating to an input user interface and an output user interface to be presented to a user in response to the associated test routine being selected, each output user interface being a simulation of the interface provided by conventional test equipment,
the processor being arranged, on selection of a particular test routine, to present to the user a user interface determined by the information associated with the test routine, the user interface being a simulation of the conventional test apparatus normally used to carry out the test routines on the system to be tested.

2. Apparatus according to claim 1 wherein the processor is arranged to identify the system to be tested connected to the connector and, in response to the identification of the connected system to be tested, to select the test routine to be performed based on the identification of the system to be tested.

3. Apparatus according to claim 2 wherein the processor is arranged to identify the system to be tested by means of an identification or address code of the system to be tested.

4. Apparatus according to claim 1 further comprising a plurality of test routines from a plurality of suppliers.

5. Apparatus according to claim 1 further comprising a modem.

6. Apparatus according to claim 1 further comprising a first unit incorporating the test routines and the associated user interface information and a second unit incorporating the user interface device and the connector.

7. Apparatus according to claim 6 wherein the first and second units are arranged to communicate via a wireless communication link, for example a radio frequency link.

8. Apparatus according to claim 6 wherein the first unit is arranged to perform as a wireless hub.

9. A method of testing a system, the method comprising:
connecting to test apparatus a system to be tested,
selecting from a plurality of test routines a test routine to be performed on the system to be tested, said plurality of test routines comprising at least one test routine for each of a plurality of systems to be tested, each test routine having associated information relating to an input user interface and an output user interface to be presented to a user in response to the associated test routine being selected,
on selection of a test routine, presenting to the user a user interface determined by the information associated with the selected test routine, the user interface being a simulation of the conventional test apparatus normally used to carry out the test routines on the system to be tested.

10. A method according to claim 9 further comprising identifying the system to be tested and, in response to the identification of the connected system to be tested, selecting the test routine to be performed based on the identification of the system to be tested.

11. A method according to claim 10 further comprising identifying the system to be tested by means of an identification or address code of the system to be tested.

12. A method according to claim 9 further comprising providing a plurality of test routines from a plurality of suppliers.

13. A computer program product comprising a computer readable medium, having thereon
computer readable program code, when said program is loaded, to make a computer execute procedure to display an interface to a user for the provision of input and output,
computer readable program code comprising a plurality of test routines, each defining a test to be performed on a system to be tested, each test routine having associated information relating to an input user interface and an output user interface to be presented to a user in response to the associated test routine being selected,
computer readable program code, when said program is loaded, to make a computer execute procedure to present to the user, on selection of a particular test routine, a user interface determined by the information associated with the test routine, the user interface being a simulation of the conventional test apparatus normally used to carry out the test routines on the system to be tested.
